(19) United States
(12) Patent Application Publication
(10) Pub. No.: US 2023/0352641 A1
(43) Pub. Date: Nov. 2, 2023

(54) DISPLAY PANEL, DISPLAY DEVICE, AND PREPARATION METHOD OF DISPLAY PANEL

(71) Applicant: Tianma Advanced Display Technology Institute (Xiamen) Co., Ltd., Xiamen (CN)

(72) Inventors: Xiaoli LIU, Xiamen (CN); Cao LIU, Xiamen (CN)

(73) Assignee: Tianma Advanced Display Technology Institute (Xiamen) Co., Ltd., Xiamen (CN)

(21) Appl. No.: 18/217,103

(22) Filed: Jun. 30, 2023

(30) Foreign Application Priority Data
Apr. 24, 2023 (CN) 202310450296.6

(51) Int. Cl. H01L 33/60; H01L 25/16; H01L 33/54

(52) U.S. Cl. CPC H01L 33/60; H01L 25/167; H01L 33/54; H01L 2933/005; H01L 2933/0058

(57) ABSTRACT

Provided are a display panel, a display device, and a preparation method of a display panel. The display panel includes a substrate, an array layer, light-emitting devices, and a first film layer. The array layer is disposed on the substrate. The light-emitting devices are arranged on a side of the array layer facing away from the substrate. The first film layer is disposed on the side of the array layer facing away from the substrate, the first film layer is provided with at least one groove, and at least part of the at least one groove is located between adjacent light-emitting devices.

### CROSS-REFERENCE TO RELATED APPLICATION

This application claims priority to Chinese Patent Application No. 202310450296.6 filed Apr. 24, 2023, the disclosure of which is incorporated herein by reference in its entirety.

### TECHNICAL FIELD

The present application relates to the field of display technologies, and in particular to, a display panel, a display device, and a preparation method of a display panel.

### BACKGROUND

With the development of micro light-emitting diode (Micro-LED) transparent display screens, the transmittance of the transparent region needs to be further improved.

During the evolution of optoelectronic technology, feature dimensions of optoelectronic assemblies continue to be miniaturized. Compared to organic light-emitting diodes (OLED), the Micro-LEDs have many advantages, such as high light-emitting efficiency, long service life, relative stability of materials that are not affected by the environment, and the ability to provide high resolution and high image quality. Therefore, display panels with micro light-emitting diode arrays have gained increasing attention to the market in recent years. However, how to improve the quality of the display panels becomes an urgent problem to be solved.

### SUMMARY

Embodiments of the present application provide a display panel, a display device, and a preparation method of a display panel, which can improve the light extraction efficiency of a display region while improving the transmittance of a transparent region.

In one aspect, a display panel is provided according to an embodiment of the present application. The display panel includes a substrate, an array layer, light-emitting devices and a first film layer. The array layer is disposed on the substrate. The light-emitting devices are arranged on a side of the array layer facing away from the substrate. The first film layer is disposed on the side of the array layer facing away from the substrate, the first film layer is provided with at least one groove, and at least part of the at least one groove is located between adjacent light-emitting devices.

In another aspect, a display device is provided according to an embodiment of the present application. The display device includes the display panel described above.

In another aspect, a preparation method of a display panel is provided according to an embodiment of the present application. The method includes that: a driving substrate is provided, where the driving substrate includes a substrate, an array layer and light-emitting devices, where the substrate, the array layer and a layer where the light-emitting devices are located are laminated in sequence; the array layer is encapsulated to form a second film layer wrapping the array layer; the light-emitting devices are encapsulated and photoetched to form a first film layer wrapping the light-emitting devices, where at least one groove is formed in the first film layer, and a groove of the at least one groove is located between adjacent light-emitting devices; a reflective layer is formed on a surface of the first film layer, where the reflective layer is attached to the surface of the first film layer; the reflective layer on the top surface of the first film layer is etched so that the reflective layer is located in the at least one groove and is attached to side walls of the first film layer.

According to the display panel, the display device, and the preparation method of a display panel provided in the embodiments of the present application, the first film layer is disposed on the light-emitting devices of the display panel, and the groove on the first film layer is disposed between adjacent light-emitting devices, whereby light emitted from the light-emitting devices is processed by using the structure of the groove on the first film layer, the light emitted from each light-emitting device at a large viewing angle is converged and finally is emitted from a front viewing angle of the light-emitting devices, so that the light extraction efficiency of the display region of the display panel is improved, and the overall light-emitting efficiency is improved, and the reduction of the light-emitting brightness is avoided.

### BRIEF DESCRIPTION OF DRAWINGS

Features, advantages and technical effects of exemplary embodiments of the present application will be described below with reference to the accompanying drawings.

FIG. 1 is a schematic plan diagram of a display panel according to an embodiment of the present application;

FIG. 2 is a schematic structural diagram of an array layer according to an embodiment of the present application;

FIG. 3 is a schematic structural diagram of a display panel according to an embodiment of the present application;

FIG. 4 is a schematic structural diagram of another display panel according to an embodiment of the present application;

FIG. 5 is a schematic structural diagram of yet another display panel according to an embodiment of the present application;

FIG. 6 is a schematic structural diagram of yet another display panel according to an embodiment of the present application;

FIG. 7 is a schematic structural diagram of yet another display panel according to an embodiment of the present application;

FIG. 8 is a schematic structural diagram of yet another display panel according to an embodiment of the present application;

FIG. 9 is a schematic structural diagram of yet another display panel according to an embodiment of the present application;

FIG. 10 is a schematic structural diagram of yet another display panel according to an embodiment of the present application;

FIG. 11 is a diagram showing a preparation process of a display panel according to an embodiment of the present application;

FIG. 12 is a diagram showing a preparation process of a display panel according to an embodiment of the present application;

FIG. 13 is a diagram showing a preparation process of a display panel according to an embodiment of the present application;

FIG. 14 is a diagram showing a preparation process of a display panel according to an embodiment of the present application;

FIG. 15 is a diagram showing a preparation process of a display panel according to an embodiment of the present application;

FIG. 16 is a diagram showing a preparation process of a display panel according to an embodiment of the present application;

FIG. 17 is a diagram showing a preparation process of a display panel according to an embodiment of the present application;

FIG. 18 is a diagram showing a preparation process of a display panel according to an embodiment of the present application;

FIG. 19 is a diagram showing a preparation process of a display panel according to an embodiment of the present application;

FIG. 20 is a flowchart of a preparation method of a display panel according to an embodiment of the present application;

FIG. 21 is a flowchart of another preparation method of a display panel according to an embodiment of the present application; and

FIG. 22 is a flowchart of yet another preparation method of a display panel according to an embodiment of the present application.

### REFERENCE LIST

100 display panel
AA display region
NA1 transparent region
NA2 wire region
10 substrate
11 adhesive layer
12 cover plate
20 array layer
21 active layer
22 gate
23 source
24 drain
25 gate insulating layer
26 intermediate layer
27 interlayer insulating layer
28 first planarization layer
29 second planarization layer
30 light-emitting device
31 anode
32 cathode
40 first film layer
41 groove
42 backup portion
50 reflective layer
51 first portion
52 second portion
60 light-shielding portion
70 second film layer
80 light-concentrating portion
90 black material layer

In the drawings, like parts use like reference numerals. The drawings are not drawn to actual scale.

### DETAILED DESCRIPTION

Features and exemplary embodiments of various aspects of the present application are described in detail below. In the following detailed description, numerous specific details are set forth in order to provide a thorough understanding of the present application. However, it will be apparent to those skilled in the art that the present application may be practiced without some details of these specific details. The following description of the embodiments is merely intended to provide a better understanding of the present application by illustrating examples of the present application. In the drawings and the following description, at least part of the well-known structures and techniques have not been shown in order to avoid unnecessarily obscuring the present application, and the dimensions of part of the structures may be exaggerated for clarity. Moreover, the features, structures, or characteristics described hereinafter may be combined in any suitable manner in one or more embodiments.

The orientation words appearing in the following description are the directions shown in the drawings and are not intended to limit the display panel, the display device and the preparation method of a display panel according to the present application. In the description of the present application, it should also be noted that, unless explicitly stated and defined otherwise, terms “mounted” and “connected” are to be understood in a broad sense. For example, the term “connected” may refer to “fixedly connected” or “detachably connected” or “integrally connected”, or may refer to “connected directly” or “connected indirectly”. For those of ordinary skill in the art, specific meanings of the preceding terms in the present application may be understood based on specific situations.

A micro light-emitting diode (Micro-LED) transparent display screen has a display region with a certain area and a transparent region with a certain area, the display region emits light, and the external light enters into the display panel from the transparent region, so that transparent display of the display panel is achieved.

Typically, since the transparent region occupies a certain area, the area reserved for the display region is limited, and in order to improve the light-emitting efficiency of the display region, it is necessary to provide a reflective bank structure between adjacent sub-pixels, and the light emitted from the sub-pixels is reflected at a reflective bank, so that the light at a large viewing angle is gathered to a front viewing angle, whereby the light-emitting brightness of the sub-pixels is improved, and the light-emitting efficiency is improved.

Nowadays, with the continuous development of the micro light-emitting diode (Micro-LED) transparent display screen, the demand on the transmittance of the transparent display screen on the market is higher and higher, and further improvement on the transmittance of the transparent display screen needs to be achieved.

However, it has found that when the transmittance is increased by increasing the area of the transparent region on the transparent display screen, the area of the display region is further reduced, so that a spacing between adjacent sub-pixels is further reduced. The dimension of the reflective bank has a certain aspect ratio, so that if the height of the reflective bank is required to be 10 μm to 15 μm, the width of the reflective bank is also required to be 10 μm to 15 μm. However, the reduction of the spacing between adjacent sub-pixels cannot support the fabrication of the reflective bank. The reflective bank does not have the dimensional condition for shaping, and finally the reflective bank is eliminated, resulting in deterioration of the light-emitting efficiency of the display region.

Based on the above-described problems, a solution of the present application is proposed.

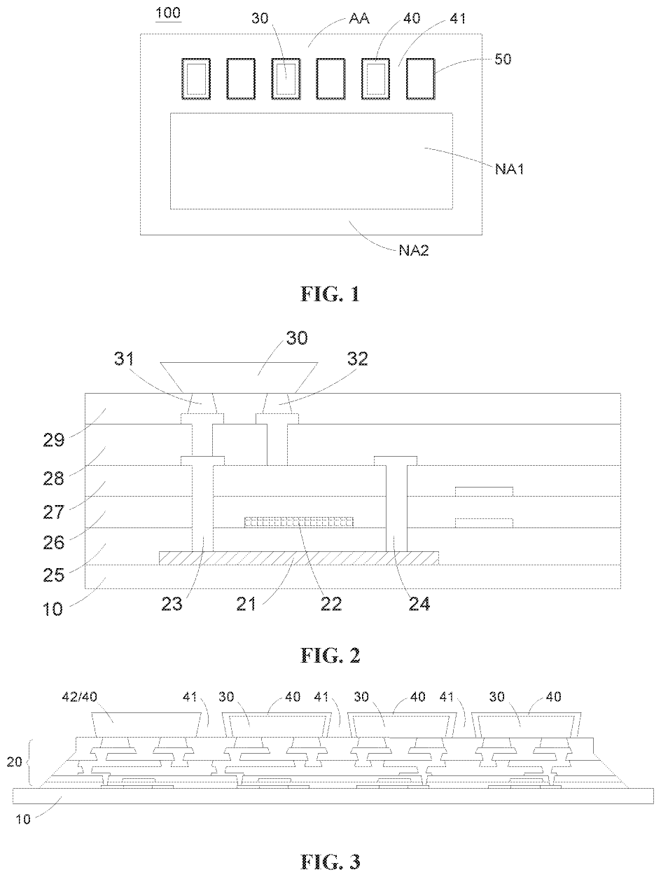

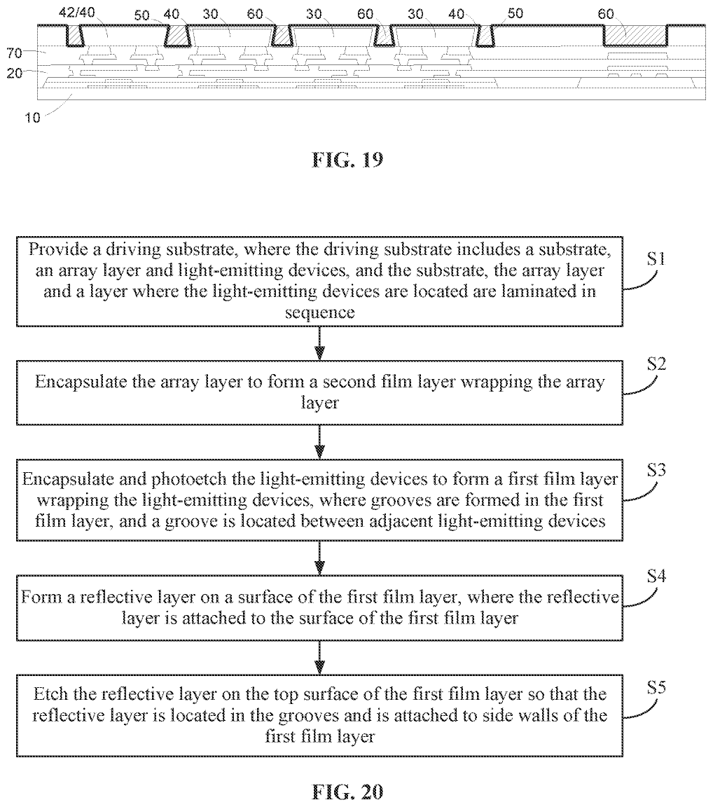

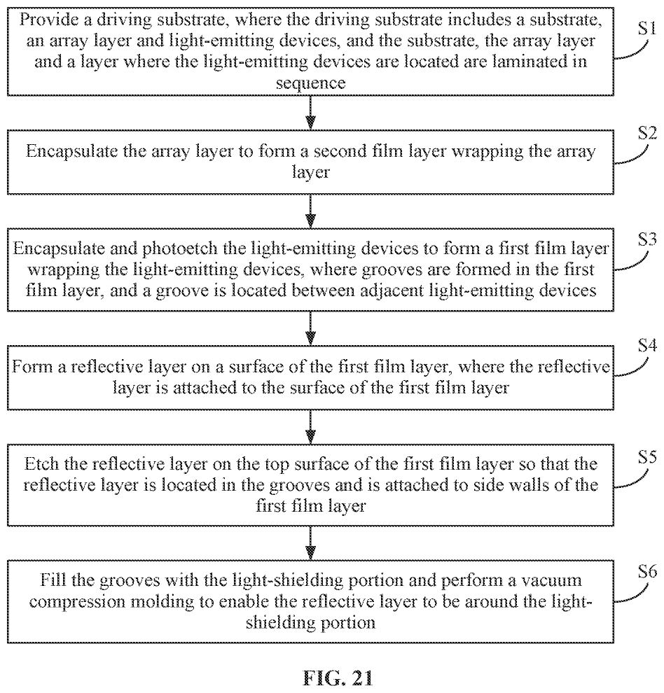

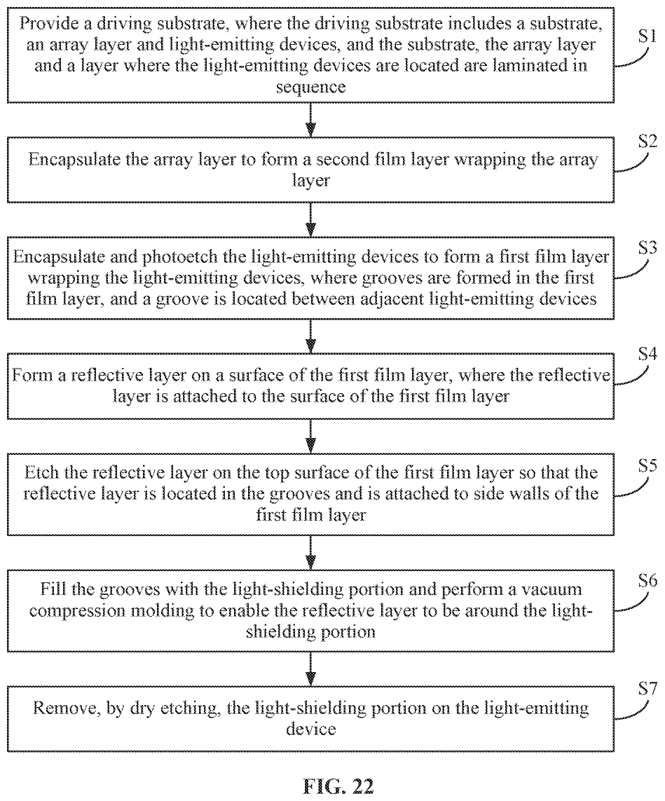

For a better understanding of the present application, a detailed description of a display panel, a display device, and a preparation method of a display panel according to an embodiment of the present application will be described below in conjunction with FIGS. 1 to 22.

Referring to FIGS. 1 to 3, an embodiment of the present application provides a display panel 100. The display panel 100 includes a substrate 10, an array layer 20, light-emitting devices 30, and a first film layer 40. The array layer 20 is disposed on the substrate 10. The light-emitting devices 30 are arranged on a side of the array layer 20 facing away from the substrate 10. The first film layer 40 is disposed on the side of the array layer 20 facing away from the substrate 10, the first film layer 40 is provided with one or more grooves 41, and at least part of the grooves 41 are located between adjacent light-emitting devices 30.

The substrate 10 in the display panel 100 may be made of a glass material as a rigid substrate, and a film layer such as a buffer film may be attached to the substrate 10.

Referring to FIG. 2, the substrate 10 is provided with the array layer 20 thereon, an anode 31 and a cathode 32 in the array layer 20 are electrically connected to the light-emitting device 30 on a surface, and the turn-on of the anode 31 and the cathode 32 drives the light-emitting device 30 to emit light. Specifically, the array layer 20 has a thin film transistor (TFT) therein which is composed of a source 23, a drain 24 and a gate 22, the source 23 or the drain 24 is connected to the anode 31 through a via, and the thin film transistor transmits a drive signal to the light-emitting device 30 so that the light-emitting device 30 emits light.

An active layer 21 in the array layer 20 may adopt low temperature polysilicon (LTPS), and the active layer 21 is connected to the source 23 and the drain 24, and film layers such as a gate insulating layer 25, an intermediate layer 26, an interlayer insulating layer 27, a first planarization layer 28 and a second planarization layer 29 are sequentially formed on the active layer 21, and the source 23 or the drain 24 sequentially passes through the film layers described above through the via and is electrically connected to the anode 31.

Optionally, the light-emitting devices 30 include a red device, a green device and a blue device which are disposed at intervals. The light-emitting devices 30 are capable of emitting red green blue (RGB) three-color light, and performing display after the color mixing is performed at a light extraction side.

Referring to FIG. 3, in this embodiment, the first film layer 40 is disposed on the array layer 20, the first film layer 40 is attached to a surface of each light-emitting device 30 of the light-emitting devices 30, and the grooves 41 are disposed on the first film layer 40 and are located between adjacent light-emitting devices 30, and this structure is capable of processing the light emitted from each light-emitting device 30 of the light-emitting devices 30 so as to improve the light-emitting brightness on the light extraction side of the light-emitting devices 30 and improve the light-emitting efficiency.

It is to be understood that the first film layer 40 is made of insulating light-transmitting materials to be able to transmit the light emitted from the light-emitting devices 30 without blocking the light, the first film layer 40 may be attached to the light-emitting devices 30 by a vapor deposition process, and the grooves 41 are formed on the first film layer 40 between adjacent light-emitting devices 30 by a photolithography process. Optionally, the first film layer 40 may be transparent photoresist.

The grooves 41 on the first film layer 40 have a smaller dimension than the reflective bank in the related art, and may be adaptively attached to the light-emitting devices 30. By means of the grooves 41, the light concentration can be achieved and the light-emitting efficiency can be increased, thereby avoiding considering a problem that a spacing between adjacent light-emitting devices 30 is too small.

According to the display panel 100 provided in the embodiments of the present application, the first film layer 40 is disposed on the light-emitting devices 30 of the display panel 100, and the groove 41 on the first film layer 40 is disposed between adjacent light-emitting devices 30, whereby the light emitted from the light-emitting devices 30 is processed by using the structure of the grooves 41 on the first film layer 40, the light emitted from each light-emitting device 30 at the large viewing angle is converged and finally is emitted from a front viewing angle of the light-emitting devices 30, so that the light extraction efficiency of the display region AA of the display panel 100 is improved, the overall light-emitting efficiency is improved, and the reduction of the light-emitting brightness is avoided.

As an optional embodiment, referring to FIG. 3, the first film layer 40 is an encapsulation layer, and the encapsulation layer covers the light-emitting devices 30 and is attached to outer walls of the light-emitting devices 30.

According to the display panel 100 provided in the embodiments of the present application, the first film layer 40 may also serves as the encapsulation layer, and the encapsulation layer can encapsulate the light-emitting devices 30, thereby preventing external moisture from entering the light-emitting devices 30 to adversely affect the light-emitting device 30. Therefore, the first film layer 40 can form the isolation protection for the light-emitting devices 30 while improving the light-emitting efficiency, so that the overall structure has the better safety performance.

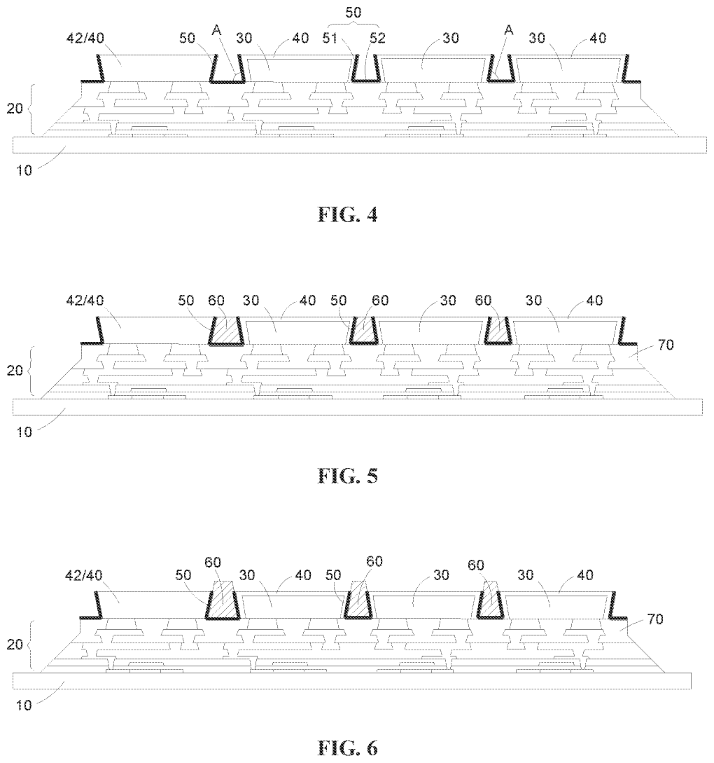

As an optional embodiment, referring to FIG. 4, the display panel 100 includes a reflective layer 50, and the reflective layer 50 is disposed in the grooves 41 and is at least partially attached to side walls of the grooves 41.

Optionally, the reflective layer 50 may be made of a metallic material, in particular, may be silver (Ag) or aluminum (Al), and the light emitted from the light-emitting devices 30 may be reflected by means of the reflective property of metal, so that the light at the large viewing angle is concentrated to the front viewing angle, thereby improving the brightness.

The reflective layer 50 mainly reflects the light emitted from a side surface of the light-emitting device 30, so that the reflective layer 50 is attached to the side walls of the groove 41, and the light passing through the groove 41 of the first film layer 40 is secondarily processed.

When the light-emitting device 30 is driven to emit light, the light emitted from the side surface of the light-emitting device 30 sequentially passes through the first film layer 40 and the reflective layer 50, and the light at the large viewing angle is sufficiently concentrated to the front viewing angle, and the arrangement of the first film layer 40 and the reflective layer 50 is not limited by the excessively small spacing between adjacent light-emitting devices 30, and has better flexibility.

For the purpose of the fabrication of the reflective layer 50, the reflective layer 50 may be formed on the first film layer 40 by a physical vapor deposition (PVD) process, and then the deposition on the light extraction side of the light-emitting device 30 is etched away to prevent the light extraction of the light-emitting device 30 from being blocked.

After the reflective layer 50 is disposed in the grooves 41, it was concluded through a simulation experiment that the light extraction energy on the light extraction side of the light-emitting device 30 is increased by 19%, the increased light-emitting efficiency is mainly concentrated in the viewing angle region ranging from 50° to 70°, and the light-emitting efficiency at the viewing angle region ranging from 0° to 2° does not change significantly.

According to the display panel 100 provided in the embodiments of the present application, the reflective layer 50 is disposed on the side walls of the grooves 41, the light of the light-emitting device 30 can be further subjected to the reflective processing, thereby further improving the light-emitting brightness at the front viewing angle and improving the light-emitting efficiency.

As an optional embodiment, referring to FIG. 4, the reflective layer 50 includes first portions 51 and second portions 52 connected to each other, the first portions 51 are attached to the side walls of the grooves 41, and the second portions 52 are attached to bottom walls of the grooves 41.

The reflective layer 50 includes a two-part structure, i.e., a first portion 51 and a second portion 52, the first portion 51 is attached to the side wall of the groove 41, and the second portion 52 is located at the bottom wall of the groove 41.

Optionally, when the reflective layer 50 is formed by the physical vapor deposition process described above, the first portion 51 and the second portion 52 are integrally formed, only the first portion 51 may function to improve the light-emitting efficiency, and the second portion 52 is formed together with the first portion 51 and is not easily removed due to the limitation of the above-described deposition process.

Since the second portion 52 is located at the bottom wall of the groove 41, the second portion 52 has a certain load-bearing capacity, and the second portion 52 is capable of carrying the upper film layer material in the groove 41. When the second portion 52 is made of a metallic material, the second portion 52 has a better load-bearing strength.

According to the display panel 100 provided in the embodiments of the present application, the secondary processing of the light is completed through the first portion 51 of the reflective layer 50, and the film layer material is carried by the second portion 52, so that the reflective layer 50 is fully utilized, whereby the multi-function utilization of the reflective layer 50 is achieved, making the reflective layer 50 versatile.

As an optional embodiment, a side wall of the groove 41 is inclined toward the middle of the groove 41 in a direction in which the substrate 10 is directed toward the array layer 20.

Optionally, in a first cross section, the light-emitting device 30 has an inverted trapezoidal structure, a short side of the inverted trapezoidal structure is connected to the array layer 20, and a long side of the inverted trapezoidal structure is located on a side facing away from the array layer 20, and correspondingly, the formed groove 41 is a regular trapezoidal structure, a long side of the regular trapezoidal structure is disposed close to the array layer 20, and a short side of the regular trapezoidal structure is disposed facing away from the array layer 20. The first cross section is a cross section perpendicular to a plane where the display panel 100 is located.

Correspondingly, if the reflective layer 50 is attached to the side walls of the groove 41, then the reflective layer 50 on the side walls of the groove 41 forms an acute angle in the groove 41 with the bottom wall of the groove 41, as shown in angle A in FIG. 4.

The light-emitting device 30 of the present application may adopt different structural shapes, and the specific structural shape of the light-emitting device 30 is not particularly limited in the present application.

According to the display panel 100 provided in the embodiments of the present application, the light-emitting device 30 is defined as a trapezoidal structure, so that it is possible to better form a gap between adjacent light-emitting devices 30, thereby facilitating the formation of the groove 41 on the first film layer 40, and finally facilitating the improvement of light-emitting efficiency.

As an optional embodiment, an included angle between the side wall of the groove 41 and a top surface of the array layer 20 ranges from 50° to 60°.

Optionally, the included angle between the side wall of the groove 41 and the top surface of the array layer 20 may be 55°. When the included angle is 55°, the simulated light-emitting efficiency is highest at this time and has a better visual effect than other angles. However, in consideration of the actual processing capability and the spacing between adjacent light-emitting devices 30, it is possible to control the angle to be greater than 55°.

For example, in the case where the spacing between adjacent light-emitting devices 30 is 7 μm, the limit of the included angle between the side wall of the groove 41 and the top surface of the array layer 20 is 63°. When the included angle is less than 63°, first film layers 40 on adjacent light-emitting devices 30 overlap and thus the reflective layer 50 cannot be formed on the side walls of the groove 41. Therefore, it is necessary to control the included angle to be greater than an included angle limit value.

It can be seen that, when the included angle is appropriately increased, an appropriate spacing is formed between adjacent light-emitting devices 30. Therefore, although the simulated light-emitting efficiency is good when the included angle is 55°, considering the spacing between adjacent light-emitting devices 30, the included angle described above is generally controlled to be greater than 55°. If the included angle is too large, then the angle of view may be contracted, whereby the range of the included angle may be controlled to be between 50° and 60° in view of the above.

Of course, a specific value of the included angle is not particularly limited in the present application as long as an appropriate spacing between adjacent light-emitting devices 30 is ensured and the viewing angle light effect requirement is satisfied.

According to the display panel 100 provided in the embodiments of the present application, by means of the simulation experiment, an included angle between the side wall of the groove 41 and the top surface of the array layer 20 is controlled to range from 50° to 60°, so that not only the overall light-emitting efficiency is improved but also the spacing requirement between adjacent light-emitting devices 30 is satisfied. Therefore, the structural conflict between adjacent light-emitting devices 30 is avoided, and thus the better adaptability is achieved.

As an optional embodiment, referring to FIG. 5, the display panel 100 further includes a light-shielding portion 60, and the light-shielding portion 60 is at least disposed in the grooves 41.

Optionally, the light-shielding portion 60 may be made of a black organic material such as a black glue. The light-shielding portion 60 is disposed in the grooves 41 to mainly absorb the excess reflected light and shield the ambient light from the outside, thereby preventing the excess light from causing an adverse effect such as crosstalk on the light extraction of the light-emitting devices 30.

The light-shielding portion 60 may be poured on the first film layer 40, and the light-shielding portion 60 may be formed in the grooves 41 by photolithography, and the residual light-shielding portion 60 may be removed by dry etching after the vacuum compression molding.

When the reflective layer 50 is disposed in the groove 41, the first portion 51 is attached to the side walls of the groove 41, and the second portion 52 is attached to the bottom wall of the groove 41. At this time, after the light-shielding portion 60 is formed in the groove 41, since the light-shielding portion 60 may be attached to the second portion 52, and the second portion 52 may carry the light-shielding portion 60, the groove 41 may provide a better accommodation for the light-shielding portion 60.

According to the display panel 100 provided in the embodiments of the present application, the light-shielding portion 60 is disposed in the grooves 41, and the light-shielding portion 60 is used for absorbing the excessive reflected light and shield the ambient light from the outside, thereby avoiding adverse effects of optical crosstalk on the light-emitting devices 30 and the array layer 20, forming a light-shielding protection for the display panel 100 as a whole, and making the display performance of the display panel 100 better.

As an optional embodiment, an absolute value of a difference between a distance from a top surface of the light-shielding portion 60 to the substrate 10 and a distance from a top surface of the light-emitting device 30 to the substrate is no more than 5 μm.

It is to be understood that the light-shielding portion 60 in the groove 41 may be provided with the height higher than the light-emitting device 30 by 5 μm or with the height lower than the light-emitting device 30 by 5 μm depending on the actual process requirements, so that the light-shielding portion 60 may be formed within a certain height range.

According to the display panel 100 provided in the embodiments of the present application, a height difference between the light-shielding portion 60 and the light-emitting device 30 is maintained between ±5 μm, so that the manufacturing process of the light-shielding portion 60 is flexible and diversified, the height of the light-shielding portion 60 is not limited to a fixed value, and when the height of the light-shielding portion 60 is other value, the light-shielding effect can be also good.

As an optional embodiment, referring to FIGS. 5 and 6, a distance from a top surface of the light-shielding portion 60 to a bottom wall of the groove 41 is greater than or equal to a distance from a top surface of the light-emitting device 30 to the top surface of the array layer 20.

When the above-described dimension requirements are satisfied, it is indicated that the grooves 41 have been sufficiently filled with the light-shielding portion 60, and the light-shielding portion 60 may be disposed flush with the light-emitting devices 30, and of course, the light-shielding portion 60 may be configured to be suitably higher than the light-emitting devices 30.

When the reflective layer 50 is disposed in the grooves 41, the light-shielding portion 60 may sufficiently cover the reflective layer 50, and specifically, may sufficiently cover the first portions 51 on the side walls of the grooves 41, so as to prevent the partial exposure of the first portion 51 from causing the light reflection, thereby affecting the display effect.

Optionally, considering that most of the light-emitting devices 30 in the current products mostly adopts the height of 7 μm, the height of the light-shielding portion 60 may be controlled to be within a range of 7 μm to 20 μm, and the light-shielding portion 60 may exert a good light absorption performance.

According to the display panel 100 provided in the embodiments of the present application, the height of the light-shielding portion 60 is set to be greater than the height of the light-emitting device 30, so that the light-shielding portion 60 can form the more sufficient coverage in the groove 41, and the front reflected light is reduced to the greatest extent by utilizing the light absorption performance of the light-shielding portion 60.

As an optional embodiment, the light-shielding portion 60 is made of a low-temperature material having a curing temperature less than 150° C.

The light-shielding portion 60 can be cured and molded more quickly by using the low-temperature material, so that a circuit device at the bottom is prevented from being affected by high temperature during the process of curing the light-shielding portion 60, thereby protecting the circuit device at the bottom.

According to the display panel 100 provided in the embodiments of the present application, the light-shielding portion 60 is made of the low-temperature material, so that curing and molding of the light-shielding portion 60 is facilitated, the damage to other components caused by the high-temperature process is avoided, and the better low-temperature protection is formed for the circuit device and the film layer.

As an optional embodiment, referring to FIG. 7, the array layer 20 includes a wire region NA2, at least part of the grooves 41 are disposed on a side of the wire region NA2 facing away from the substrate 10, and the light-shielding portion 60 is disposed in the groove 41.

Optionally, the wire region NA2 on the array layer 20 includes an RGB data line, a PVDD wire, a PVEE wire, and the like. The wire region NA2 is disposed around the transparent region NA1 and the display region AA, that is, the wire region NA2 is located at a non-display region AA.

Considering that the light shielding protection is performed on each circuit wire in the wire region NA2, and the wire region NA2 is prevented from being affected by external ambient light, the groove 41 on the first film layer 40 may be disposed at a corresponding position of the wire region NA2, and the groove 41 may be filled with the light-shielding portion 60, so that the light entering the wire region NA2 from the outside is absorbed by the light absorption characteristic of the light-shielding portion 60, thereby forming the light shielding protection for the wire region NA2.

As can be seen from the above arrangement, the light-shielding portion 60 needs to be disposed between adjacent light-emitting devices 30 of the display region AA and surrounded on the transparent region NA1 and the wire region NA2 of the display region AA, so that the light-shielding portion 60 integrally forms the light shielding protection for the display panel 100, thereby providing the better display effect.

After the light-shielding portion 60 is used for forming the light shielding protection for the display panel 100 as a whole, an encapsulation film processing may be performed, and an adhesive connection may be formed between the adhesive layer 11 and the cover plate 12. Optionally, the adhesive layer 11 may be an optically clear adhesive (OCA)/optical clear resin (OCR), and the cover plate 12 may be made of a glass material.

According to the display panel 100 provided in the embodiments of the present application, the light-shielding portion 60 is disposed in the groove 41 of the first film layer 40 on the wire region NA2, so that the light shielding protection is formed for a signal wire in the wire region NA2, thereby avoiding the influence of external ambient light on the wire region NA2, and enabling the display panel 100 to have the better safety performance.

As an optional embodiment, the display panel 100 further includes a second film layer 70, the second film layer 70 is disposed on the array layer 20 and encapsulates the array layer 20, and the grooves 41 are disposed on a side of the second film layer 70 facing away from the array layer 20.

Optionally, the second film layer 70 is an encapsulation layer, and the second film layer 70 is capable of forming the encapsulation protection for the array layer 20 to prevent external moisture from entering the array layer 20, thereby avoiding adverse effects on circuit devices in the array layer 20, and the second film layer 70 may encapsulate the array layer 20 by the deposition process.

When the reflective layer 50 is disposed in the grooves 41 of the first film layer 40, since the reflective layer 50 may be a metal layer, the encapsulation of the array layer 20 by the second film layer 70 may isolate the reflective layer 50 from the array layer 20, thereby avoiding a short circuit caused by the direct contact between the reflective layer 50 and the array layer 20.

According to the display panel 100 provided in the embodiments of the present application, the array layer 20 is encapsulated by the second film layer 70, so that an isolation protection is formed for the array layer 20, and the second film layer 70 may also carry the grooves 41 of the first film layer 40 and the reflective layer 50 while preventing external moisture from entering the array layer 20, thereby avoiding the influence of the reflective layer 50 on the array layer 20, and enabling the display panel 100 to have the better safety performance.

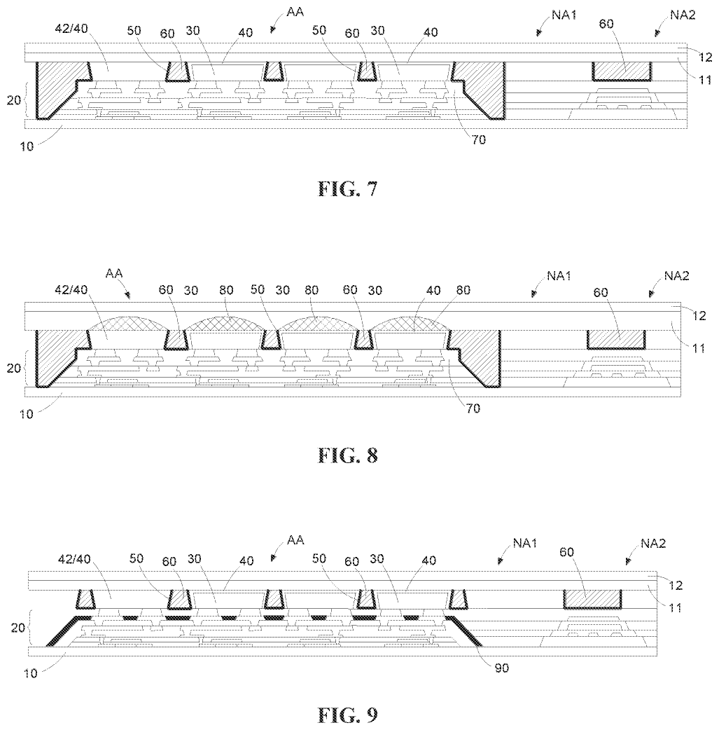

As an optional embodiment, referring to FIG. 8, the display panel 100 further includes light-concentrating portions 80, a light-concentrating portion 80 is disposed in correspondence with a light-emitting device 30, and the light-concentrating portions 80 are located on a side of the light-emitting devices 30 facing away from the array layer 20.

Optionally, the light-concentrating portion 80 may be a convex lens, the light-concentrating portion 80 have a certain refractive index, and the light-concentrating portions 80 are disposed on the light extraction side of the light-emitting devices 30, so that the light emitted from the light-emitting devices 30 may be refracted and processed.

The light-concentrating portion 80 may be disposed on the light extraction side of each light-emitting device 30, and the light-concentrating portion 80 may increase the light extraction of the light-emitting device 30 while further improving the brightness at the front viewing angle of the light-emitting device 30 in cooperation with the reflective layer 50 in the groove 41.

According to the display panel 100 provided in the embodiments of the present application, the light-concentrating portions 80 are disposed on the light extraction side of the light-emitting devices 30, whereby the light at the large viewing angle can be further converged, so that the light is emitted from the front viewing angle, the display brightness at the front viewing angle is improved, and the overall light extraction effect is improved.

As an optional embodiment, a refractive index of the light-concentrating portions 80 is between 1.5 and 2.3.

According to the display panel 100 provided in the embodiments of the present application, the refractive index of the light-concentrating portions 80 obtained through the simulation experiment is between 1.5 and 2.3, so that the light can be better extracted, the display panel 100 has better light-emitting efficiency, and when the refractive index of the light-concentrating portions 80 is too small or too large, the light cannot be converged to the front viewing angle.

As an optional embodiment, a refractive index of the first film layer 40 is between 1.5 and 2.6.

According to the display panel 100 provided in the embodiments of the present application, the first film layer 40 is encapsulated to the surface of the light-emitting devices 30 so that the refractive index thereof is between 1.5 and 2.6, and light emitted from the light-emitting device 30 can be better extracted, whereby the light at the large viewing angle is converged to the front viewing angle, thereby improving the light effect at the front viewing angle.

As an optional embodiment, the first film layer 40 includes a backup portion 42, the backup portion 42 is disposed on the side of the array layer 20 facing away from the substrate 10, the backup portion 42 covers a redundant electrode on the array layer 20, and at least part of the grooves 41 are disposed between the backup portion 42 and light-emitting devices 30.

In this embodiment, the backup portion 42 may be disposed at an adjacent side of the light-emitting device 30, and the backup portion 42 may be formed of the first film layer 40, and the backup portion 42 is connected to the redundant electrode in the array layer 20 so as to perform a backup function thereof.

Here, the backup portion 42 is formed when the first film layer 40 is manufactured. As a redundant replacement of the light-emitting device 30, the backup portion 42 does not emit light. When the backup portion 42 is replaced, the backup portion 42 needs to be removed by laser etching and a light-emitting device 30 is mounted, and finally, the replacement is completed.

In consideration of the light-emitting property of the backup portion 42 after being replaced with the light-emitting device 30, the groove 41 on the first film layer 40 is located between the backup portion 42 and the adjacent light-emitting device 30, so that the light-emitting device 30 at the backup portion 42 may be adjusted in light-emitting efficiency. Similarly, the reflective layer 50 and the light-shielding portion 60 may be disposed in the groove 41 between the backup portion 42 and the light-emitting device 30, the reflective layer 50 may reflect and converge the light at the large viewing angle, and the light-shielding portion 60 may reduce the front reflected light and the external ambient light.

According to the display panel 100 provided in the embodiments of the present application, the backup portion 42 is disposed adjacent to the light-emitting device 30, and the light-emitting device 30 may be replaced by the backup portion 42, thereby providing a reliable guarantee for effective light-emitting.

In the present application, considering that light emitted from the bottom of the light-emitting device 30 may affect the array layer 20, the array layer 20 may be light-shielded by using a black material to absorb the reverse lights of the light-emitting device 30. As shown in FIG. 9, the array layer 20 may be light-shielded as a whole, and the array layer 20 may be sufficiently covered by the black material layer 90, so that the light at the bottom of the light-emitting device 30 may be prevented from entering the array layer 20.

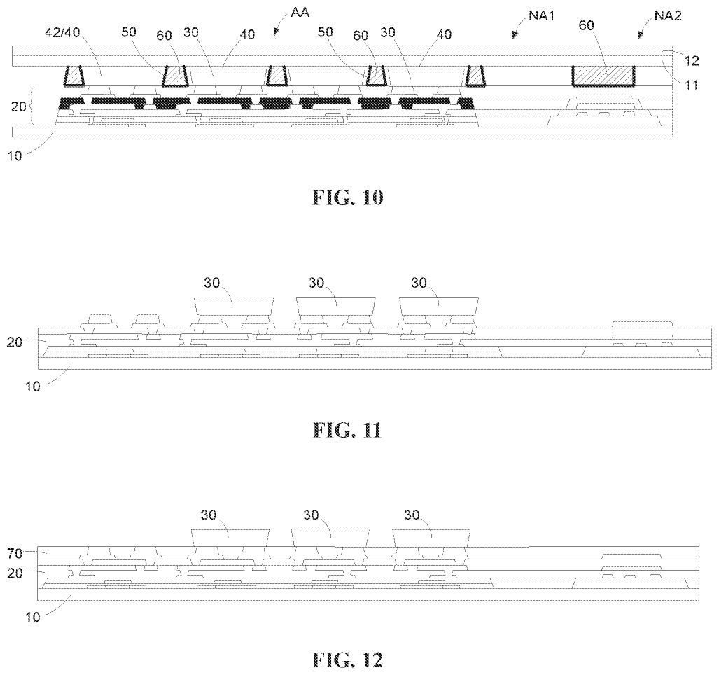

Optionally, as shown in FIG. 10, the black material layer 90 may be provided between any two of the layers in the array layer 20 as long as it is ensured that the black material layer 90 may cover the thin film transistor, thereby avoiding undesirable effects of light on the thin film transistor, and improving the light leakage current of the thin film transistor.

The black material layer 90 may be made of a high-temperature material having a curing temperature greater than 230° C., so that cracking of the light-emitting device 30 during bonding can be prevented.

Therefore, the black material layer 90 is provided to form the light shielding protection for the array layer 20, so that the influence of light on the array layer 20 is avoided, the display panel 100 has better safety performance, and a reliable guarantee is provided for improving the light extraction effect.

An embodiment of the present application provides a display device including the display panel 100 as described above.

An embodiment of the present application provides a preparation method of a display panel. The method includes the following steps. In S1, a driving substrate is provided, where the driving substrate includes a substrate 10, an array layer 20 and light-emitting devices 30, and the substrate 10, the array layer 20 and a layer where the light-emitting devices 30 are located are laminated in sequence. In S2, the array layer 20 is encapsulated to form a second film layer 70 wrapping the array layer 20. In S3, the light-emitting devices 30 are encapsulated and photoetched to form a first film layer 40 wrapping the light-emitting devices 30, where grooves are formed in the first film layer 40, and a groove 41 is located between adjacent light-emitting devices 30. In S4, a reflective layer 50 is formed on a surface of the first film layer 40, where the reflective layer 50 is attached to the surface of the first film layer 40. In S5, the reflective layer 50 on the top surface of the first film layer 40 is etched so that the reflective layer 50 is located in the grooves 41 and is attached to side walls of the first film layer 40.

Referring to FIG. 11, in step S1, the provided driving substrate is a backplane on which the light-emitting devices 30 are bonded, the light-emitting devices 30 have been electrically connected to the array layer 20, and on the basis of this, the light-emitting efficiency improvement is performed.

Referring to FIGS. 12 and 13, in steps S2 and S3, the second film layer 70 and the first film layer 40 are sequentially formed by the vapor deposition process, the array layer 20 is encapsulated by the second film layer 70, and after the first film layer 40 is disposed, the first film layer 40 is patterned by photolithography to form the grooves 41.

Optionally, steps S2 and S3 may be processed synchronously.

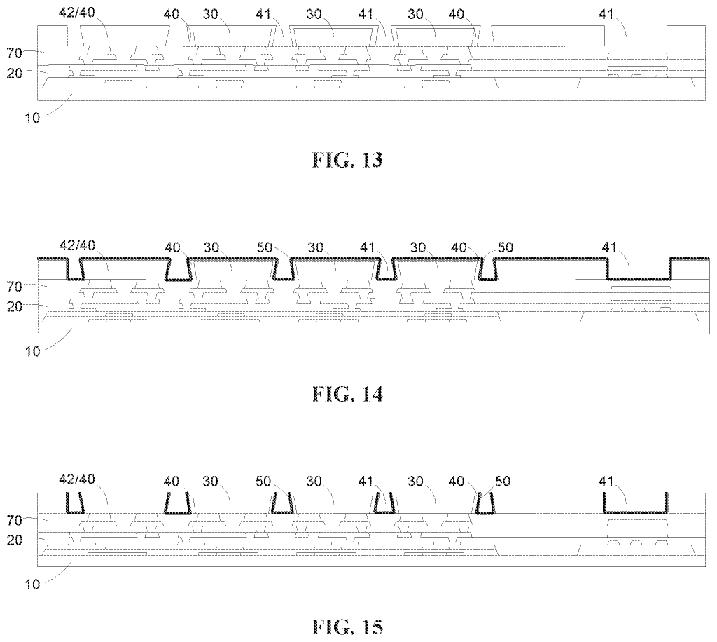

Referring to FIG. 14, in step S4, the reflective layer 50 is evaporated to the surface of the first film layer 40 by the vapor deposition process. Optionally, the reflective layer 50 may be a metal layer such as silver (Ag), aluminum (Al), copper (Cu), or molybdenum (Mo).

Referring to FIG. 15, in step S5, the reflective layer 50 formed on the top surface of the first film layer 40 is etched and removed to prevent the reflective layer 50 formed on the top surface of the first film layer 40 from causing a light-shielding effect on the light-emitting devices 30, and only the reflective layer 50 at the side walls is retained.

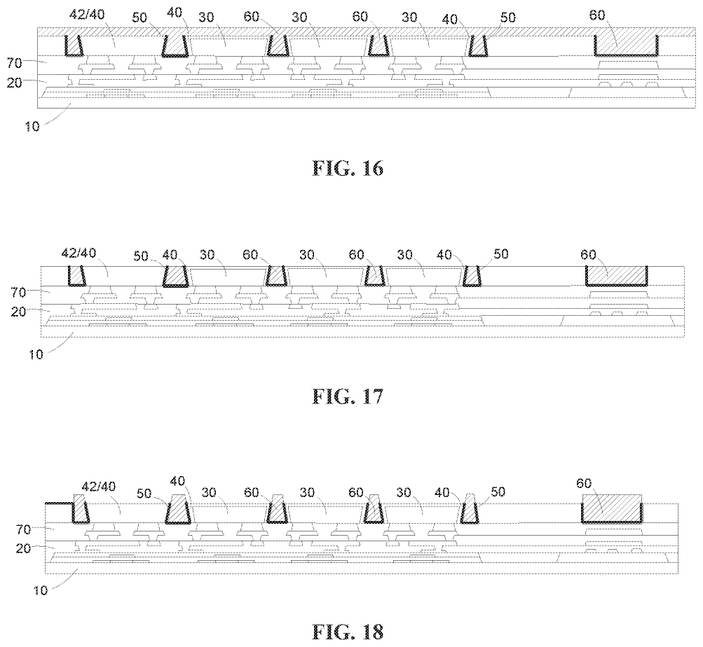

As an optional embodiment, referring to FIGS. 16 to 19, the method further includes the steps described below. In S6, the grooves 41 are filled with the light-shielding portion 60 and a vacuum compression molding is performed to enable the reflective layer 50 to be around the light-shielding portion 60.

After the above-described structure is formed, the light-shielding portion 60 is poured and patterned by photolithography, so that the light-shielding portion 60 is located in the grooves 41, and then the light-shielding portion 60 is cured and molded, thereby absorbing excess reflected light by the light-shielding portion 60.

Optionally, in the above steps, the operation sequences of S5 and S6 may be interchanged without affecting the final molding structure.

As an optional embodiment, the method further includes the steps described below. In S7, the light-shielding portion 60 on the light-emitting devices 30 is removed by dry etching.

In consideration of a fact that when the light-shielding portion 60 is formed, the excess residual material is disposed on the light-emitting devices 30 to shield light from the light-emitting devices 30, the residual material may be removed by a dry etching process.

For the overall flow of the preparation method of the display panel 100 described above, reference may be made to FIGS. 20 to 22.

According to the display panel, the display device, and the preparation method of a display panel provided in the embodiments of the present application, the first film layer is disposed on the light-emitting devices of the display panel, the groove on the first film layer is disposed between adjacent light-emitting devices, whereby light emitted from the light-emitting devices is processed by using the structure of the grooves on the first film layer, the light emitted from each light-emitting device at the large viewing angle is converged and finally is emitted from the front viewing angle of the light-emitting devices, so that the light extraction efficiency of the display region of the display panel is improved, and the overall light-emitting efficiency is improved, and the reduction of the light-emitting brightness is avoided.

Although the present application has been described with reference to preferred embodiments, various modifications may be made thereto and equivalents may be substituted for components thereof without departing from the scope of the present application. In particular, each of the technical features mentioned in the various embodiments may be combined in any manner as long as there is no structural conflict. The present application is not limited to the specific embodiments disclosed herein, but includes all technical schemes falling within the scope of the claims.

What is claimed is:

1. A display panel, comprising:
a substrate;
an array layer disposed on the substrate;
light-emitting devices arranged on a side of the array layer facing away from the substrate; and
a first film layer disposed on the side of the array layer facing away from the substrate, wherein the first film layer is provided with at least one groove, and at least part of the at least one groove is located between adjacent light-emitting devices.

2. The display panel of claim 1, wherein the first film layer is an encapsulation layer, and the encapsulation layer covers the light-emitting devices and is attached to outer walls of the light-emitting devices.

3. The display panel of claim 1, further comprising:
a reflective layer disposed in the at least one groove and at least partially attached to side walls of the at least one groove.

4. The display panel of claim 3, wherein the reflective layer comprises first portions and a second portion connected to each other, the first portions are attached to the side walls of the at least one groove, and the second portion is attached to a bottom wall of the at least one groove.

5. The display panel of claim 1, wherein a side wall of a groove of the at least one groove is inclined toward a middle of the groove in a direction in which the substrate is directed toward the array layer.

6. The display panel of claim 5, wherein an included angle between the side wall of the groove and a top surface of the array layer ranges from 50° to 60°.

7. The display panel of claim 1, further comprising:
a light-shielding portion at least disposed in the at least one groove.

8. The display panel of claim 7, wherein an absolute value of a difference between a distance from a top surface of the light-shielding portion to the substrate and a distance from a top surface of a light-emitting device of the light-emitting devices to the substrate is no more than 5 μm.

9. The display panel of claim 7, wherein a distance from a top surface of the light-shielding portion to a bottom wall of a groove of the at least one groove is greater than or equal to a distance from a top surface of a light-emitting device of the light-emitting devices to a top surface of the array layer.

10. The display panel of claim 7, wherein the light-shielding portion is made of a low-temperature material having a curing temperature less than 150° C.

11. The display panel of claim 1, wherein the array layer comprises a wire region, at least part of the at least one groove is disposed on a side of the wire region facing away from the substrate, and a light-shielding portion is disposed in the at least one groove.

12. The display panel of claim 1, further comprising:
a second film layer, wherein the second film layer is disposed on the array layer and encapsulates the array layer, and the at least one groove is disposed on a side of the second film layer facing away from the array layer.

13. The display panel of claim 1, further comprising:
light-concentrating portions, wherein a light-concentrating portion of the light-concentrating portions is disposed in correspondence with a light-emitting device of the light-emitting devices and the light-concentrating portions are located on a side of the light-emitting devices facing away from the array layer.

14. The display panel of claim 13, wherein a refractive index of the light-concentrating portions is between 1.5 and 2.3.

15. The display panel of claim 1, wherein a refractive index of the first film layer is between 1.5 and 2.6.

16. The display panel of claim 1, wherein the first film layer comprises a backup portion, the backup portion is disposed on the side of the array layer facing away from the substrate, the backup portion covers a redundant electrode on the array layer, and at least part of the at least one groove is disposed between the backup portion and a light-emitting device of the light-emitting devices.

17. A display device comprising a display panel, wherein the display panel comprises:
a substrate;
an array layer disposed on the substrate;
light-emitting devices arranged on a side of the array layer facing away from the substrate; and
a first film layer disposed on the side of the array layer facing away from the substrate, wherein the first film layer is provided with at least one groove, and at least part of the at least one groove is located between adjacent light-emitting devices.

18. A preparation method of a display panel, comprising:
providing a driving substrate, wherein the driving substrate comprises a substrate, an array layer, and light-emitting devices, wherein the substrate, the array layer, and a layer where the light-emitting devices are located are laminated in sequence;
encapsulating the array layer to form a second film layer wrapping the array layer;
encapsulating and photoetching the light-emitting devices to form a first film layer wrapping the light-emitting devices, wherein at least one groove is formed in the first film layer, and a groove of the at least one groove is located between adjacent light-emitting devices;
forming a reflective layer on a top surface of the first film layer, wherein the reflective layer is attached to the top surface of the first film layer; and
etching the reflective layer on the top surface of the first film layer so that the reflective layer is located in the at least one groove and is attached to side walls of the first film layer.

19. The preparation method of a display panel of claim 18, further comprising:
filling the at least one groove with a light-shielding portion and performing a vacuum compression molding to enable the reflective layer to be around the light-shielding portion.

20. The preparation method of a display panel of claim 19, further comprising:
removing the light-shielding portion on the light-emitting devices by dry etching.
